(19) United States
(12) Patent Application Publication
(10) Pub. No.: US 2020/0158677 A1
(43) Pub. Date: May 21, 2020

(54) DETECTING DEVICE

(71) Applicant: MINEBEA MITSUMI Inc., Nagano (JP)

(72) Inventor: Taketomo NAKANE, Tokyo (JP)

(21) Appl. No.: 16/663,625

(22) Filed: Oct. 25, 2019

(30) Foreign Application Priority Data
Nov. 16, 2018 (JP) 2018-215854
Nov. 16, 2018 (JP) 2018-215856

(51) Int. Cl. G01N 27/22; H01L 21/761

(52) U.S. Cl. CPC G01N 27/227; H01L 21/761; G01N 27/223; G01N 27/226

(57) ABSTRACT

A detecting device includes a semiconductor substrate and a detecting unit disposed over the semiconductor substrate, the detecting unit being configured to output a signal in response to a physical property. The detecting device includes a noise suppressing layer disposed below the detecting unit and in the semiconductor substrate, or, disposed between the detecting unit and the semiconductor substrate.

### CROSS-REFERENCE TO RELATED APPLICATION

This application claims priority under 35 U.S.C. § 119 to Japanese Patent Application Nos. 2018-215854, filed on Nov. 16, 2018, and 2018-215856, filed on Nov. 16, 2018, the contents of which are incorporated herein by reference in their entirety.

### BACKGROUND OF THE INVENTION

### 1. Field of the Invention

The present disclosure relates to a detecting device such as a humidity detecting unit.

### 2. Description of the Related Art

Some humidity detecting devices as examples of detecting devices are capacitance types in which a moisture sensitive film is used as a dielectric substance, the moisture sensitive film being formed of a high polymer material of which a permittivity changes according to an amount of absorbed water. With respect to such a capacitance type humidity detecting device, a moisture sensitive film is disposed between electrodes, and humidity (relative humidity) is obtained by measuring capacitance possessed between the electrodes (e.g., Japanese Patent No. 5547296 referred to as Patent Document 1).

In the humidity detecting device disclosed in Patent Document 1, a sensor unit and a circuit unit are arranged together on a substrate of the humidity detecting device. The sensor unit changes capacitance in accordance with humidity, and the circuit unit converts an electric charge carried by the sensor unit into a voltage, or the like.

The circuit unit used in such a humidity detecting device of the capacitive type is known to convert an electric charge carried by the sensor unit into a voltage, by a charge amplifier (e.g., Japanese Patent No. 6228865 referred to as Patent Document 2). In addition to the charge amplifier, the circuit unit includes a drive circuit that drives the sensor unit in accordance with an alternating current (AC) drive signal as a rectangular wave.

### SUMMARY OF THE INVENTION

The present disclosure provides a detecting device including: a semiconductor substrate; a detecting unit disposed over the semiconductor substrate, the detecting unit being configured to output a signal in response to a physical property; and a noise suppressing layer disposed below the detecting unit and in the semiconductor substrate, or, disposed between the detecting unit and the semiconductor substrate.

### BRIEF DESCRIPTION OF THE DRAWINGS

FIG. 1 is a diagram schematically illustrating an example of a configuration of a humidity detecting device according to a first embodiment;

FIG. 2 is a schematic cross-sectional view taken along the A-A line in FIG. 1;

FIG. 3 is a plan view of an example of the humidity detecting device from which mold resin is removed;

FIG. 4 is a schematic plan view of an example of a configuration of a sensor chip;

FIG. 5 is a circuit diagram illustrating an example of a configuration of an ESD protection circuit;

FIG. 6 is a diagram illustrating an example of a layer structure of an NMOS transistor that constitutes the ESD protection circuit;

FIG. 7 is a circuit diagram illustrating an example of a configuration of a humidity detecting unit;

FIG. 8 is a schematic cross-sectional view for explaining an example of an element structure of the sensor chip;

FIG. 9 is a plan view of an example of the shape of a lower electrode and an upper electrode;

FIG. 10 is a diagram illustrating an example of a configuration of an ASIC chip;

FIG. 11 is a timing chart for explaining an example of a measurement sequence;

FIG. 12 is a schematic cross-sectional view for explaining an example of an element structure of the sensor chip according to a second embodiment;

FIG. 13 is a schematic cross-sectional view for explaining an example of an element structure of the sensor chip according to a third embodiment;

FIG. 14 is a plan view of an example of a humidity detecting device from which mold resin is removed according to a fourth embodiment;

FIG. 15 is a schematic plan view of an example of a configuration of a sensor chip according to the fourth embodiment;

FIG. 16 is a circuit diagram illustrating an example of a configuration of an ESD protection circuit according to the fourth embodiment;

FIG. 17 is a diagram illustrating an example of a layer structure of an NMOS transistor that constitutes the ESD protection circuit according to the fourth embodiment;

FIG. 18 is a circuit diagram illustrating an example of a configuration of a temperature detecting unit according to the fourth embodiment;

FIG. 19 is a schematic cross-sectional view for explaining an example of an element structure of the sensor chip according to the fourth embodiment;

FIG. 20 is a plan view of an example of a guard ring and the shape of n-type diffusion layers that constitute a heating unit;

FIG. 21 is a diagram illustrating an example of an equivalent circuit of a noise suppressing unit according to the fourth embodiment; and

FIG. 22 is a diagram illustrating an example of a configuration of an ASIC chip according to the fourth embodiment.

### DESCRIPTION OF THE PREFERRED EMBODIMENTS

With respect to the humidity detecting device disclosed in Patent Document 1, the sensor unit and the circuit unit are arranged together. In this regard, the inventor has recognized that there is a need for downsizing and low costs of the device. For this reason, it is considered that the sensor unit and the circuit unit are integrated as a chip, the device being considered to have a structure in which the sensor unit is stacked on the circuit unit.

When the sensor unit and the circuit unit are arranged together, the influence on noise transmitted from their units is decreased because the units are placed so as to be away from each other. However, if the sensor unit is stacked on the circuit unit, the influence on the noise may be increased because their units are placed more closely.

In particular, as described above, when the circuit unit drives the sensor unit by the AC drive signal, large noise may be generated by both of the sensor unit and the circuit unit.

In view of the issue recognized by the inventor, one or more embodiments provide detecting devices whereby it is possible to improve protection against the noise.

One or more embodiments will be hereinafter explained with reference to the drawings. In each figure, the same reference numerals are used to denote same elements; accordingly, for the elements described once, the explanation may be omitted. Note that in the present disclosure, humidity when simply referred to as humidity means relative humidity.

### First Embodiment

### [Outline Configuration]

A configuration of a humidity detecting device 10 will be described according to a first embodiment.

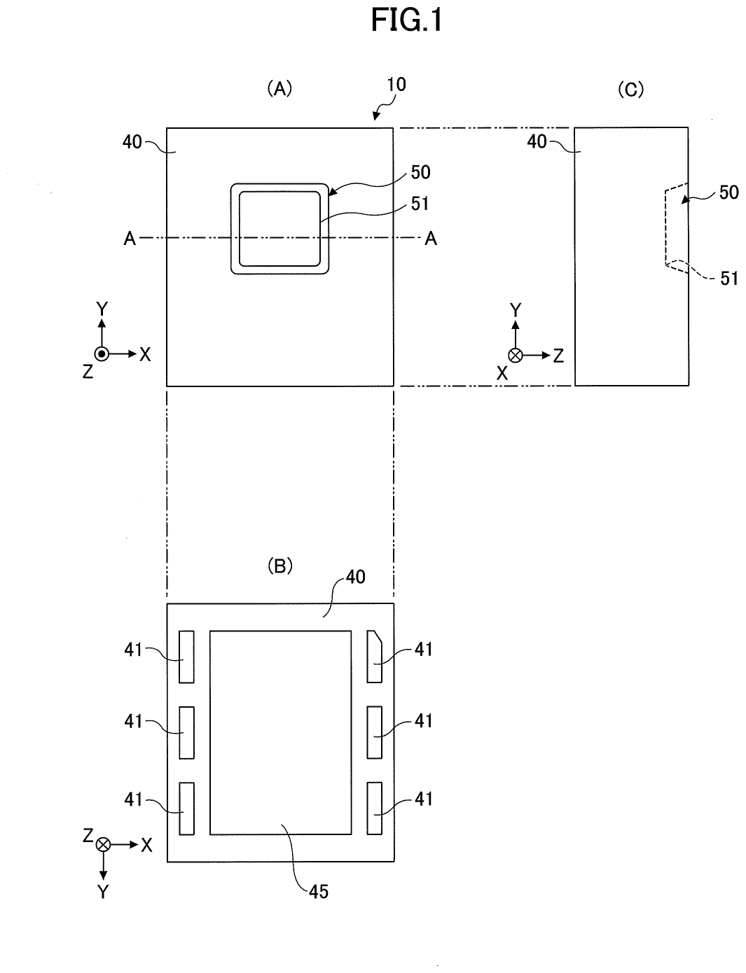

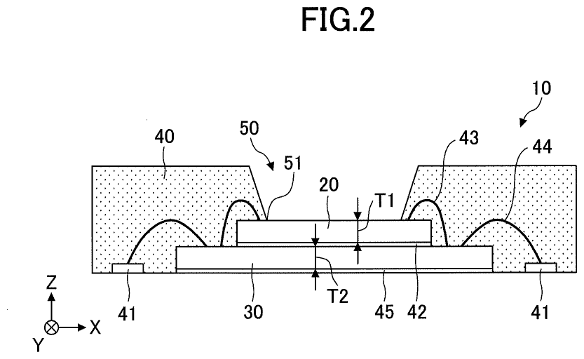

FIG. 1 is a diagram schematically illustrating an example of a configuration of the humidity detecting device 10 according to the first embodiment. FIG. 1 (A) is a plan view of the humidity detecting device 10 when viewed from an upper surface thereof. FIG. 1 (B) is a bottom view of the humidity detecting device 10 when viewed from a lower surface thereof. FIG. 1 (C) is a side view of the humidity detecting device 10 when viewed from a lateral direction. FIG. 2 is a schematic cross-sectional view taken along the A-A line in FIG. 1 (A).

The humidity detecting device 10 has an approximately rectangular shape in which one of two opposite pairs of sides is parallel to an X direction and another is parallel to a Y direction. The X and Y directions are perpendicular to each other. The humidity detecting device 10 has a thickness in a Z direction perpendicular to the X direction and the Y direction. Note that the planar shape of the humidity detecting device 10 is not limited to a rectangle, and may be a circle, an ellipse, a polygon, or the like.

The humidity detecting device 10 includes a sensor chip 20 as a first semiconductor chip, an ASIC (Application Specific Integrated Circuit) chip 30 as a second semiconductor chip, mold resin 40 as a sealing member, and a plurality of lead terminals 41.

The sensor chip 20 is disposed on the ASIC chip 30 via a first DAF (Die Attach Film) 42. In such a manner, the sensor chip 20 and the ASIC chip 30 are stacked.

The sensor chip 20 and the ASIC chip 30 are electrically connected to each other by a plurality of first bonding wires 43. The ASIC chip 30 and the plurality of lead terminals 41 are electrically connected to each other by a plurality of second bonding wires 44.

The stacked sensor chip 20 and ASIC chip 30, the plurality of first bonding wires 43, the plurality of second bonding wires 44, and the plurality of lead terminals 41 are sealed with the mold resin 40 to form a package. Such a packaging manner is also referred to as a PLP (Plating Lead Package) manner.

As described in detail below, on a lower surface of the ASIC chip 30, a second DAF 45 used when packaged in the PLP manner remains. The second DAF 45 serves to insulate the lower surface of the ASIC chip 30. The second DAF 45 and the plurality of lead terminals 41 are exposed on a lower surface of the humidity detecting device 10.

Each lead terminal 41 is formed of nickel or copper. Each of the first DAF 42 and the second DAF 45 is formed of an insulating material made of a mixture of resin and silica or the like. The mold resin 40 is black resin capable of shielding light, such as epoxy resin containing mixtures of carbon black, silica, and the like.

An opening 50 is formed on an upper surface of the humidity detecting device 10 to expose a portion of the sensor chip 20 from the mold resin 40. For example, a wall portion forming the opening 50 is tapered, and an opening area of the opening 50 becomes smaller toward the bottom. With respect to the opening 50, a lowest opening that actually exposes the sensor chip 20 is referred to as an effective opening 51.

In forming the opening 50, the sensor chip 20 is sealed with the mold resin 40 while a mold is pressed into the sensor chip 20. In this case, with respect to each of the sensor chip 20 and the ASIC chip 30, due to a force of being pushed by the mold, breakage such as a crack in a chip may occur. To prevent such breakage, each of a thickness T1 of the sensor chip 20 and a thickness T2 of the ASIC chip 30 is preferably 200 μm or more.

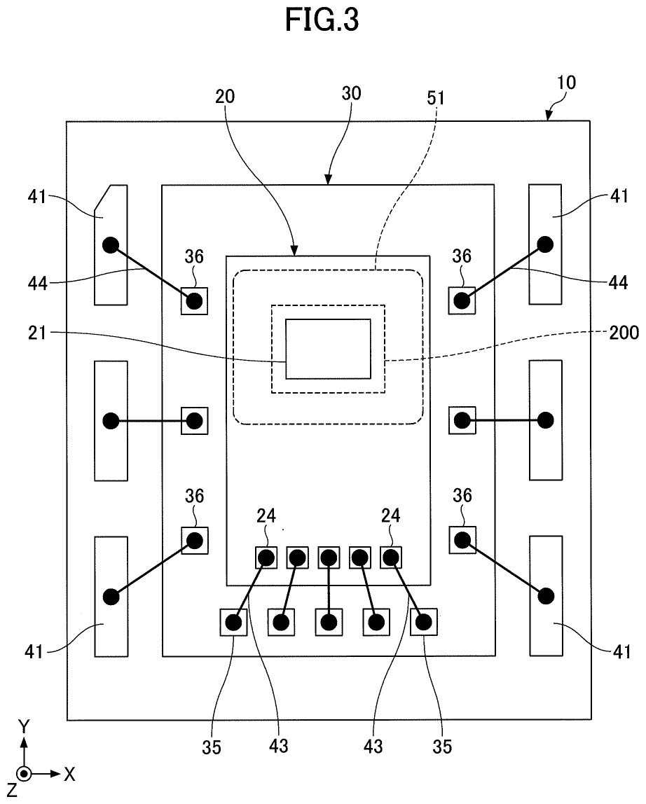

FIG. 3 is a plan view of an example of the humidity detecting device 10 from which the mold resin 40 is removed. As illustrated in FIG. 3, with respect to each of the sensor chip 20 and the ASIC chip 30, the planar shape is an approximate rectangle that has two sides parallel to the X direction and two sides parallel to the Y direction. The sensor chip 20 is smaller than the ASIC chip 30, and is disposed on a surface of the ASIC chip 30 via the first DAF 42.

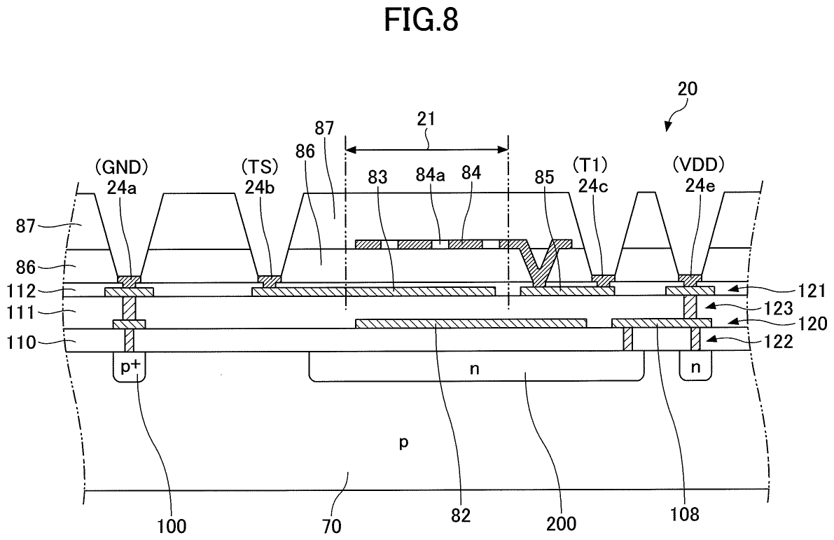

With respect to the sensor chip 20, a humidity detecting unit 21 is provided in an area exposed by the effective opening 51. Also, in a p-type semiconductor substrate 70 (see FIG. 8), a noise suppressing layer 200 for suppressing noise is provided on the underside of the humidity detecting unit 21.

A plurality of bonding pads (which are hereafter simply referred to as pads) 24 are formed in an end portion of the sensor chip 20. In the present embodiment, five pads 24 are formed. The pads 24 are formed of aluminum or an aluminum-silicon alloy (AlSi), for example.

The ASIC chip 30 is a semiconductor chip for signal processing and control, and performs the operation described below.

On a surface of the ASIC chip 30, a plurality of first pads 35 and a plurality of second pads 36 are also provided in a region that is not covered by the sensor chip 20. Each of the first and second pads 35 and 36 is formed of aluminum or an aluminum-silicon alloy (AlSi), for example.

The first pads 35 are connected to the respective pads 24 of the sensor chip 20 via the first bonding wires 43. The second pads 36 are connected to the respective lead terminals 41 via the second bonding wires 44. Each of the lead terminals 41 is disposed in the surroundings of the ASIC chip 30.

[Configuration of Sensor Chip]

Hereafter, a configuration of the sensor chip 20 will be described.

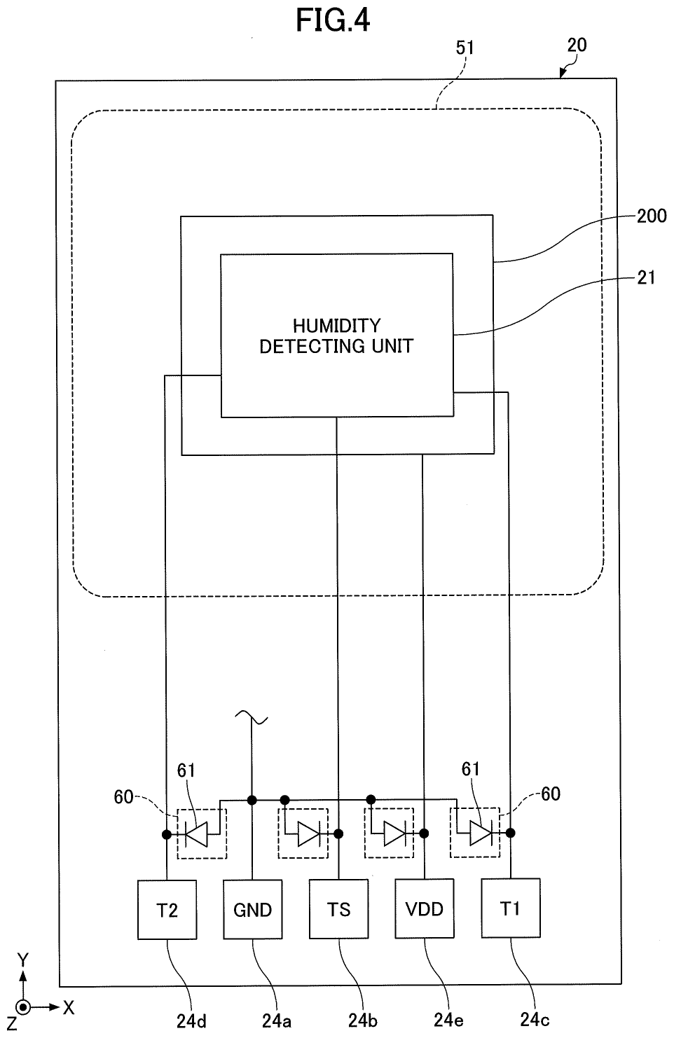

FIG. 4 is a schematic plan view of an example of a configuration of a sensor chip 20. The pads 24 are terminals that are used for applying a voltage from the external or detecting an electric potential. In FIG. 4, the respective pads 24 illustrated in FIG. 3 are distinctively indicated by pads 24a to 24e. Note that when it is not necessary to distinguish between the pads 24a and 24e, they may be simply referred to as pads 24.

A pad 24a serves as a ground electrode terminal (GND) that is grounded to a ground potential. The pad 24a is electrically connected to the p-type semiconductor substrate 70 (see FIG. 8) that constitutes part of the sensor chip 20.

A pad 24b is a signal terminal TS that is electrically connected to a lower electrode 83 of the humidity detecting unit 21. A pad 24c is a first drive terminal T1 that is electrically connected to an upper electrode 84 of the humidity detecting unit 21. A pad 24d is a second drive terminal T2 that is electrically connected to a reference electrode 82 (see FIG. 8) of the humidity detecting unit 21.

A pad 24e is a power supply terminal (VDD) for supplying a power supply voltage. The pad 24e is electrically connected to the noise suppressing layer 200.

Electrostatic-static discharge (ESD) protection circuits 60 are respectively connected to the pads 24b to 24e other than the pad 24a. Each ESD protection circuit 60 is connected between the pad 24a as a ground electrode terminal and a given pad as an input terminal or an output terminal from among the pads 24b to 24e. In the present embodiment, each ESD protection circuit 60 includes one diode 61. An anode of the diode 61 is connected to the pad 24a, and a cathode is connected to a given pad among the pads 24b to 24e.

Each ESD protection circuit 60 is preferably disposed in proximity to the pads 24b to 24e so as to be as far as possible away from the effective opening 51. Each ESD protection circuit 60 is sealed with the mold resin 40. Thereby, unwanted charge caused by the photoelectric effect is not generated.

[Configuration of ESD Protection Circuit]

Hereafter, a configuration of the ESD protection circuit 60 will be described.

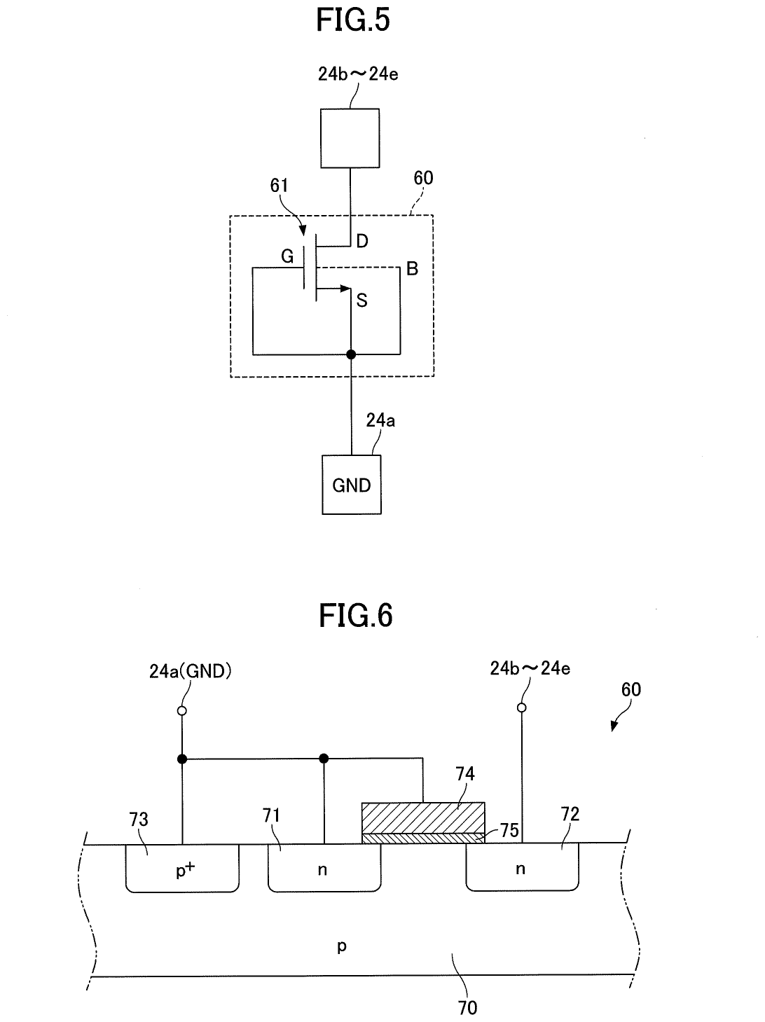

FIG. 5 is a circuit diagram illustrating an example of a configuration of the ESD protection circuit 60. As illustrated in FIG. 5, a diode 61 that constitutes the ESD protection circuit 60 is formed by an N-channel MOS (Metal-Oxide-Semiconductor) transistor (which is hereafter referred to as an NMOS transistor), for example. Specifically, the diode 61 is formed by short-circuiting (so-called diode connection) a source, a gate, and a back gate of the NMOS transistor. Such a short circuit serves as an anode. A drain of the NMOS transistor serves as a cathode.

FIG. 6 is a diagram illustrating an example of a layer structure of the NMOS transistor that constitutes the ESD protection circuit 60. The NMOS transistor has two n-type diffusion layers 71 and 72, each of which is formed in a surface layer of the p-type semiconductor substrate 70 for constituting part of the sensor chip 20, a contact layer 73, and a gate electrode 74. The gate electrode 74 is formed on a surface of the p-type semiconductor substrate 70 via a gate insulating film 75. The gate electrode 74 is disposed between the two n-type diffusion layers 71 and 72.

For example, the n-type diffusion layer 71 serves as a source, and the n-type diffusion layer 72 serves as a drain. The contact layer 73 is a low resistance layer (p-type diffusion layer) for an electrical connection to the p-type semiconductor substrate 70 as a back gate. The n-type diffusion layer 71, the gate electrode 74, and the contact layer 73 are commonly connected to be short-circuited. Such a short circuit serves as an anode, and the n-type diffusion layer 72 serves as a cathode.

The p-type semiconductor substrate 70 is a p-type silicon substrate, for example. The gate electrode 74 is formed of metal or polycrystalline silicon (polysilicon). For example, the gate insulating film 75 is formed by an oxide film such as silicon dioxide.

[Configuration of Humidity Detecting Unit]

Hereafter, a configuration of the humidity detecting unit 21 will be described.

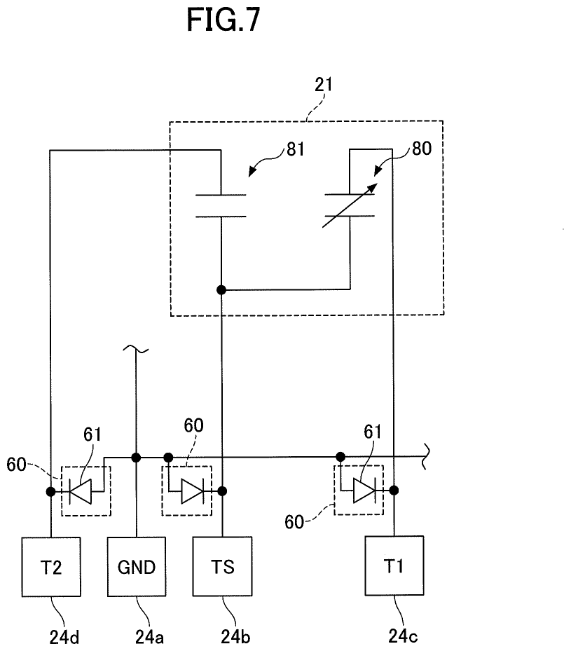

FIG. 7 is a circuit diagram illustrating an example of a configuration of the humidity detecting unit 21. As illustrated in FIG. 7, the humidity detecting unit 21 includes a capacitor 80 for humidity detection and a capacitor 81 for reference.

One electrode (the lower electrode 83) of the humidity detecting unit 21 is connected to the pad 24b as the signal terminal TS. Another electrode (the upper electrode 84) of the humidity detecting unit 21 is connected to the pad 24c as the first drive terminal T1. One electrode of the capacitor 81 for reference is common to the one electrode (the lower electrode 83) of the humidity detecting unit 21. Another electrode (the reference electrode 82) of the capacitor 81 for reference is connected to the pad 24d as the second drive terminal T2.

A moisture sensitive film 86 is provided between the electrodes of the capacitor 80 for humidity detection, as described below. The moisture sensitive film 86 is formed of a high polymeric material such as polyimide, which absorbs moisture of the air and changes a permittivity according to an amount of absorbed water. The capacitor 80 for humidity detection changes capacitance in accordance with an amount of moisture absorbed by the moisture sensitive film 86.

A second insulating film 111 (see FIG. 8) is provided between the electrodes of the capacitor 81 for reference, as described below. The second insulating film 111 is formed of an insulating material such as silicon dioxide (SiO₂) which does not absorb moisture. Accordingly, capacitance of the capacitor 81 for reference either does not change or any change is negligible.

An amount of moisture contained in the moisture sensitive film 86 changes depending on humidity in the surroundings of the humidity detecting device 10. In this case, relative humidity can be measured by detecting a difference between capacitance of the capacitor 80 for humidity detection and capacitance of the capacitor 81 for reference. Such relative humidity is measured by the ASIC chip 30.

[Element Structure of Sensor Chip]

Hereafter, an element structure of the sensor chip 20 will be described.

FIG. 8 is a schematic cross-sectional view for explaining an example of an element structure of the sensor chip 20. Note that in FIG. 8, the pads 24a, 24b, 24c and 24e are illustrated in a same cross section as the humidity detecting unit 21, for facilitating understanding of the structure. This, however, does not mean that the pads are actually present in a same cross section. Also, a cross-section of the humidity detecting unit 21 is simplified to facilitate understanding of the structure.

As illustrated in FIG. 8, the sensor chip 20 is formed using the p-type semiconductor substrate 70 described above. In a surface layer of the p-type semiconductor substrate 70, a noise suppressing layer 200 and a contact layer 100 are formed. The noise suppressing layer 200 is formed by an n-type diffusion layer that has an opposite polarity of the p-type semiconductor substrate 70. The contact layer 100 is formed by a p-type diffusion layer.

Each layer in the p-type semiconductor substrate 70 is formed by a general semiconductor manufacturing process (CMOS process). The noise suppressing layer 200 can also be formed by a same manufacturing process as the n-type diffusion layers 71 and 72 of the ESD protection circuit 60. The noise suppressing layer 200 and the n-type diffusion layers 71 and 72 are formed by an ion-implantation process in which a substrate is doped with an impurity used in ion implantation of an n-type impurity (e.g., phosphorus).

Note that the noise suppressing layer 200 and the n-type diffusion layers 71 and 72 can be formed by a heating diffusion process in which an impurity is added by heat treatment, instead of an ion implantation process.

A first insulating film 110, the second insulating film 111, and a third insulating film 112 are sequentially laminated on the surface of the p-type semiconductor substrate 70. These are formed of an insulating material such as silicon dioxide (SiO₂) or silicon nitride (SiN).

A first interconnect layer 120 is formed on the first insulating film 110. A second interconnect layer 121 is formed on the second insulating film 111. The first interconnect layer 120 is overlaid with the second insulating film 111. The second interconnect layer 121 is overlaid with the third insulating film 111. Each of the first interconnect layer 120 and the second interconnect layer 121 is formed of a conductive material such as aluminum.

A first plug layer 122 that has a plurality of first plugs for connecting the first interconnect layer 120 to the p-type semiconductor substrate 70 is formed in the first insulating film 110. A second plug layer 123 that has a plurality of second plugs for connecting the first interconnect layer 120 to the second interconnect layer 121 is formed in the second insulating film 111. Each of the first plug layer 122 and the second plug layer 123 is formed of a conductive material such as tungsten.

An interconnect 108 for applying a power supply voltage to the noise suppressing layer 200 is formed by the first interconnect layer 120. One end of the interconnect 108 is connected to the noise suppressing layer 200 via the first plug layer 122, and another end of the interconnect 108 is connected to the pad 24e via the second plug layer 123 and the second interconnect layer 121.

The reference electrode 82 used for the capacitor 81 for reference is formed by the first interconnect layer 120, and is connected to the pad 24d (not shown in FIG. 8) as the second drive terminal T2, via the second plug layer 123 and the second interconnect layer 121.

The lower electrode 83 used for the capacitor 80 for humidity detection is formed by the second interconnect layer 121, and is connected to the pad 24b as the signal terminal TS. Further, an interconnect 85 for connecting the upper electrode 84 of the capacitor 80 for humidity detection to the pad 24c as the first drive terminal T1, is formed by the second interconnect layer 121. Note that the lower electrode 83 is disposed at a location opposite to the reference electrode 82, via the second insulating film 111.

Each of the pads 24a to 24e is formed of a conductive material such as aluminum, and is disposed on the third insulating film 112. Each of the pads 24a to 24e is connected to the second interconnect layer 121, passing through the third insulating film 112.

The moisture sensitive film 86 is formed on the third insulating film 112. The moisture sensitive film 86 has a thickness of 0.5 μm to 1.5 μm, and is formed of a polymeric material that is capable of easily absorbing and desorbing the water molecule in accordance with the humidity. The moisture sensitive film 86 is a polyimide film that has a thickness of 1 μm, for example. Note that a polymeric material that forms the moisture sensitive film 86 is not limited to polyimide, and may include cellulose, polymethyl methacrylate (PMMA), polyvinyl alcohol (PVA), or the like.

An upper surface of the moisture sensitive film 86 is flat, and on this upper surface, a flat-plate type upper electrode 84 is formed. The upper electrode 84 is formed at a location opposite to the lower electrode 83, via the moisture sensitive film 86. A portion of the upper electrode 84 is connected to the interconnect 85. For example, the upper electrode 84 is a conductive film that is formed of aluminum metal that has a thickness of 200 nm, or the like. A plurality of openings 84a are also formed in the upper electrode 84 in order to efficiently incorporate water molecules in the air into the moisture sensitive film 86.

An overcoat film 87 is disposed on the moisture sensitive film 86 so as to cover the upper electrode 84. The overcoat film 87 is formed of a polymeric material, e.g., a same material as the moisture sensitive film 86. A thickness of the overcoat film 87 is 0.5 μm to 10 μm, for example.

Openings are formed in the moisture sensitive film 86 and the overcoat film 87 in order to expose the pads 24a to 24e.

In such a manner, the capacitor 80 for humidity detection, which is a parallel-plate type, is configured by the lower electrode 83 and the upper electrode 84. Also, the capacitor 81 for reference, which is a parallel-plate type, is configured by the lower electrode 83 and the reference electrode 82. The capacitor 80 for humidity detection as well as the capacitor 81 for reference are disposed over the noise suppressing layer 200. In other words, the reference electrode 82 is disposed between the noise suppressing layer 200 and the lower electrode 83.

By applying a power supply voltage to the noise suppressing layer 200, a p-n junction formed between the noise suppressing layer 200 and the p-type region of the p-type semiconductor substrate 70 is reverse-biased, so that a depletion layer is thereby increased.

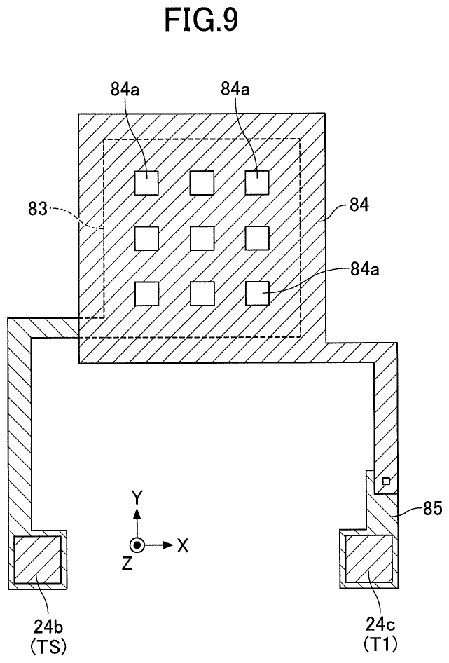

FIG. 9 is a plan view illustrating an example of the shape of the lower electrode 83 and the upper electrode 84. As illustrated in FIG. 9, each of the lower electrode 83 and the upper electrode 84 has a rectangular shape. The upper electrode 84 is formed so as to cover lower electrode 83.

A given opening 84a is preferably as small as possible. In such a manner, leakage of an electric field in the air is prevented as each opening 84a is small. In the present embodiment, many openings 84a are formed. Note that the shape of each opening 84a is not limited to a square, and may be an elongated rectangle, or a circle. The openings 84a may be arranged in a staggered pattern. Preferably, circular openings 84a may be arranged in a staggered pattern.

Note that although not illustrated in FIG. 9, a rectangular reference electrode 82 is formed below the lower electrode 83.

[Configuration of ASIC Chip]

Hereafter, a configuration of the ASIC chip 30 will be described.

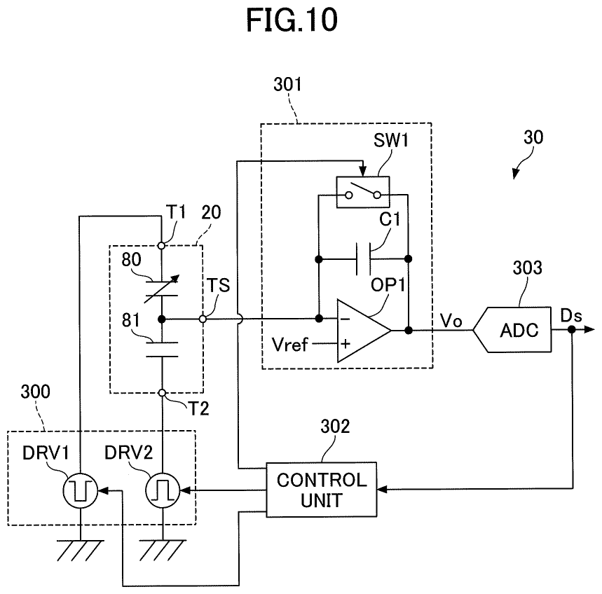

FIG. 10 is a block diagram illustrating an example of a configuration of the ASIC chip 30. As illustrated in FIG. 10, the ASIC chip 30 includes a drive unit 300, a charge amplifier 301, a control unit 302, and an AD converter (ADC) 303.

The drive unit 300 includes a first drive circuit DRV1 and a second drive circuit DRV2. The charge amplifier 301 is a charge-voltage converting (CV converting) unit that includes a capacitor C1, an operational amplifier OP1, and a switch circuit SW1.

The first drive circuit DRV1 applies a first drive signal, which is an alternating current (AC) drive signal as a rectangular wave, to the first drive terminal T1 of the sensor chip 20, under control of the control unit 302. The second drive circuit DRV2 applies a second drive signal to the second drive terminal T2 of the sensor chip 20, under control of the control unit 302. The second drive signal is an AC drive signal as a rectangular wave, and has an opposite phase of the first drive signal. For example, each of the first drive signal and the second drive signal reaches a same high level as the power supply voltage VDD, and falls to a same low level as the ground potential GND.

The first drive signal and the second drive signal have opposite phases. That is, when the first drive signal reaches a high level, the second drive signal falls to a low level, and when the first drive signal falls to a low level, the second drive signal reaches a high level.

One end of the capacitor C1 is connected to the signal terminal TS of the sensor chip 20, and another end of the capacitor C1 is connected to the output of the operational amplifier OP1.

An inverting input terminal of the operational amplifier OP1 is connected to the signal terminal TS, and a reference voltage Vref is inputted to a non-inverting input terminal of the operational amplifier OP1. For example, the reference voltage Vref is taken as a value intermediate between a high level and a low level, with respect to a first drive signal and a second drive signal.

Because the voltage gain of the operational amplifier OP1 is very high, a voltage at the signal terminal TS is approximately the same as the reference voltage Vref. Further, because an input impedance of the inverting input terminal of the operational amplifier OP1 is very high, almost no current flows into the inverting input terminal. The operational amplifier OP1 applies a voltage Vo that expresses an increased difference between a voltage at the signal terminal TS and a reference voltage Vref.

The switch circuit SW1 is a circuit for discharging an electric charge stored by the capacitor C1, and is connected in parallel with the capacitor C1. The switch circuit SW1 is turned on or off under control of the control unit 302.

The ADC 303 converts an output voltage Vo of the operational amplifier OP1 into a digital signal Ds, under control of the control unit 302.

The control unit 302 controls each unit in the ASIC chip 30. The control unit 302 follows a predetermined measurement sequence to: cause the drive unit 300 to generate a drive signal; cause the discharge from the capacitor C1 by the switch circuit SW1; and cause the ADC 303 to perform analog-to-digital conversion.

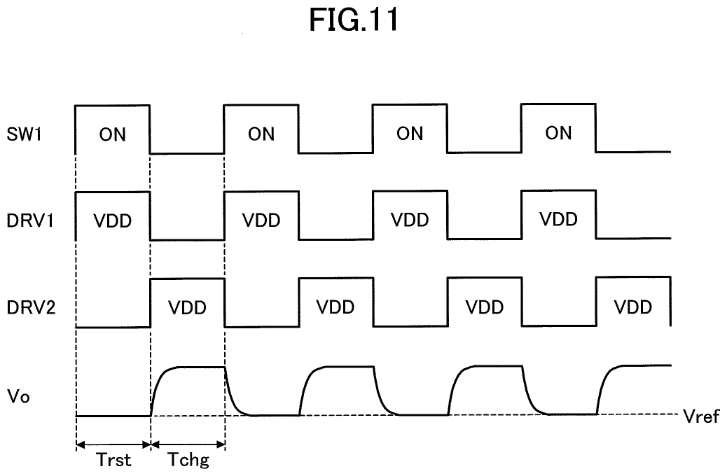

FIG. 11 is a timing chart for explaining the measurement sequence. In the measurement sequence, the control unit 302 controls each unit such that a reset period Trst and a charge-transfer period Tchg are alternately repeated. In the reset period Trst, the control unit 302 turns on the switch circuit SW1 to cause the capacitor C1 to discharge an electric charge, while setting a first drive signal at a high level and setting a second drive signal at a low level. In the charge-transfer period Tchg, the control unit 302 turns off the switch circuit SW1 to cause the capacitor C1 to be rechargeable, while setting a first drive signal at a low level and setting a second drive signal at a high level.

Under such control, in the charge transfer period Tchg, the charge amplifier 301 supplies a voltage Vo as expressed by Equation (1) below.

Vo=VDD×(Cs−Cr)/C1+Vref (1)

Where Cs denotes capacitance of the capacitor 80 for humidity detection, and Cr denotes capacitance of the capacitor 81 for reference.

The control unit 302 performs a process of humidity calculation using a digital signal Ds outputted from the ADC 303 to calculate relative humidity (% RH).

[Effects]

In the measurement sequence, the humidity detecting unit 21 of the sensor chip 20 receives a first drive signal and a second drive signal each of which is an AC signal. Accordingly, each of an electric potential at the upper electrode 84 of the capacitor 80 for humidity detection and an electric potential at the reference electrode 82 of the capacitor 81 for reference is temporally inverted repeatedly. In such a manner, each of the capacitor 80 for humidity detection and the capacitor 81 for reference constantly changes a potential difference between the electrodes, so that a current flows to one or more interconnects, which are each connected to a corresponding electrode, in accordance with the potential being inverted.

If the noise suppressing layer 200 is not disposed, a current flows from the humidity detecting unit 21 to the p-type semiconductor substrate 70, which would result in a noise source. If noise is generated in the p-type semiconductor substrate 70, the noise might affect the operation of the ASIC chip 30. Further, the noise generated in the ASIC chip 30 might affect the operation of the sensor chip 20. In order to suppress the effect of such noise in the chips, it could be considered to interpose an insulating layer between the chips. However, it is undesirable to dispose the insulating layer between the chips because there is a need for downsizing and thinning of each chip.

In light of the point recognized by the inventor, in the present embodiment, the noise suppressing layer 200 to which a constant potential is applied is disposed in the surface layer of the p-type semiconductor substrate 70 that is positioned below the humidity detecting unit 21. Thereby, a current flowing from the humidity detecting unit 21 to the p-type semiconductor substrate 70 is decreased, and thus the generation of noise is suppressed. The noise suppressing layer 200 also reduces the effect of noise on the humidity detecting unit 21, caused by the ASIC chip 30.

In the present embodiment, the noise suppressing layer 200 is described as using an n-type diffusion layer, and a constant potential is applied to the noise suppressing layer 200 such that a p-n junction between the noise suppressing layer 200 and the p-type semiconductor substrate 70 is reverse-biased. Thereby, a depletion layer is increased, and thus protection against the noise is improved.

Note that in the present embodiment, the constant potential applied to the noise suppressing layer 200 is described as using the power supply voltage VDD that has a same level as a high level of a drive signal for driving the sensor chip 20. However, the constant potential preferably has a greater value than the high level of the drive signal.

In the present embodiment, the noise suppressing layer 200 is formed in the surface layer of the p-type semiconductor substrate 70. However, the noise suppressing layer 200 is not limited to being formed in the surface layer of the p-type semiconductor substrate 70, and may be formed more deeply in the p-type semiconductor substrate 70.

### Second Embodiment

Hereafter, a humidity detecting device will be described according to a second embodiment.

In the first embodiment, the polarity of the semiconductor substrate that constitutes part of the sensor chip is p-type. However, the second embodiment will be described as using n-type as an example for the polarity of the semiconductor substrate.

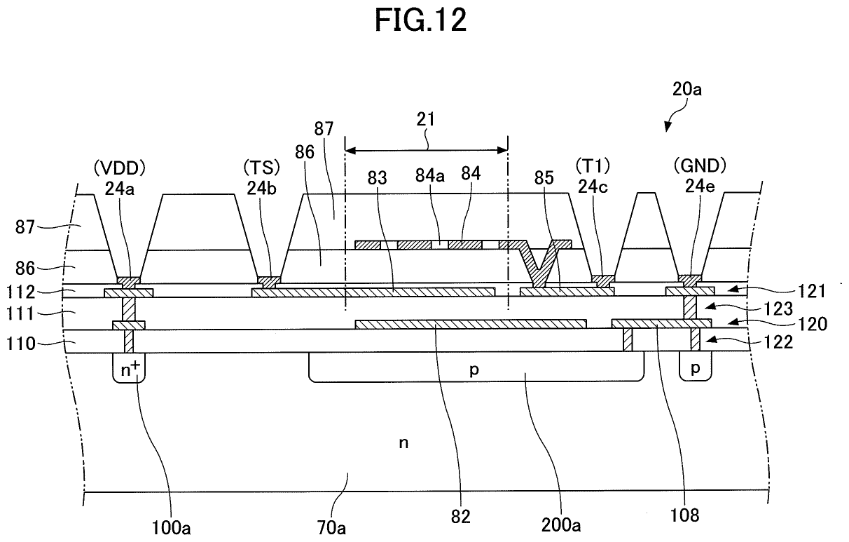

FIG. 12 is a schematic cross-sectional view for explaining an element structure of a sensor chip 20a according to the second embodiment. In the present embodiment, an n-type semiconductor substrate 70a includes a noise suppressing layer 200a as a p-type diffusion layer, and includes a contact layer 100a as an n-type diffusion layer.

In the present embodiment, with a power supply voltage VDD being applied to a pad 24a, a high potential is applied to the n-type semiconductor substrate 70a. Also, in the present embodiment, with the pad 24e being grounded to a ground potential GND, the noise suppressing layer 200a has a low potential. Thus, in the present embodiment as well, a p-n junction between the noise suppressing layer 200 and the n-type semiconductor substrate 70a is reverse-biased, so that a depletion layer is increased.

In the present embodiment, each ESD protection circuit 60 is also configured by the n-type semiconductor substrate 70a. In this case, each diffusion layer has an opposite polarity of that in the first embodiment.

A configuration of a humidity detecting device according to the present embodiment is the same as the humidity detecting device according to the first embodiment, except that each layer of the semiconductor substrate according to the present embodiment has an opposite polarity of that in the first embodiment.

The humidity detecting device according to the present embodiment has a same effect as the humidity detecting device according to the first embodiment.

Note that the noise suppressing layer 200a is not limited to being formed in the surface layer of the n-type semiconductor substrate 70a, and may be formed more deeply in the n-type semiconductor substrate 70a.

### Third Embodiment

Hereafter, a humidity detecting device will be described according to a third embodiment.

In each of the first embodiment and the second embodiment, the noise suppressing layer is formed in the semiconductor substrate. However, the third embodiment will be described as using a noise suppressing layer formed above a semiconductor substrate.

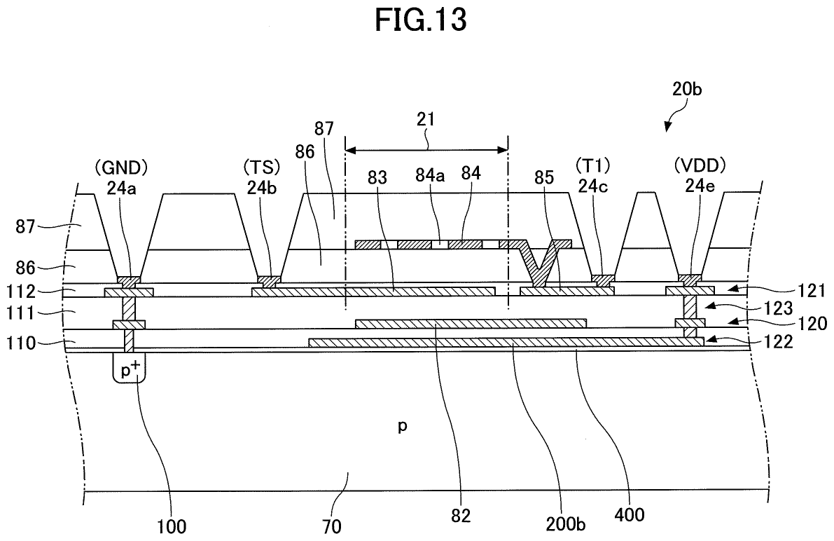

FIG. 13 is a schematic cross-sectional view for explaining an element structure of a sensor chip 20b according to the third embodiment. In the present embodiment, a noise suppressing layer 200b is provided above a p-type semiconductor substrate 70 via an insulating film 400.

The insulating film 400 is a layer corresponding to a gate insulating film 75 of each ESD protection circuit 60, and is formed in a same manufacturing process as the gate insulating film 75. Although the insulating film 400 is also disposed in each of the sensor chips 20 and 20a in the first and second embodiments, it is not illustrated in each of FIGS. 8 and 12.

The noise suppressing layer 200b is a conductive layer formed of metal or polycrystalline silicon. The noise suppressing layer 200b is a layer corresponding to a gate electrode 74 of each ESD protection circuit 60, and is formed in a same manufacturing process as the gate electrode 74.

A constant potential is applied to the noise suppressing layer 200b. Specifically, the noise suppressing layer 200b is electrically connected to a pad 24e, and a power supply voltage VDD is applied to the noise suppressing layer 200b via the pad 24e. Note that the constant potential applied to the noise suppressing layer 200b is not limited to the power supply voltage VDD, and may be higher than the power supply voltage VDD.

In the present embodiment, the noise suppressing layer 200b to which a constant potential is applied is provided between the humidity detecting unit 21 and the p-type semiconductor substrate 70. Thereby, a current flowing from the humidity detecting unit 21 to the p-type semiconductor substrate 70 is decreased, so that the generation of noise is thereby suppressed. The noise suppressing layer 200 also reduces the effect of noise on the humidity detecting unit 21, caused by the ASIC chip 30.

The present embodiment is described as using p-type as an example for the polarity of the semiconductor substrate. However, the polarity of the semiconductor substrate can be n-type in a same manner as the second embodiment.

<Modifications>

Modifications will be described below.

In each embodiment, the noise suppressing layer and each ESD protection circuit are formed in the semiconductor substrate that constitutes part of the sensor chip. However, a temperature detecting unit may be further formed in the semiconductor substrate. The temperature detecting unit may be formed by an npn-type or pnp-type bipolar transistor, one or more p-n junction diodes, an impurity diffusion layer as a resistor, or the like. The temperature detecting unit is preferably formed in a location exposed from an opening 50. The temperature detecting unit can be formed by a same manufacturing process as the noise suppressing layer or the ESD suppressor circuit.

In each embodiment, the noise suppressing layer is disposed below the humidity detecting unit to suppress noise against the humidity detecting unit. However, the noise suppressing layer may be disposed immediately below one or more interconnects that are connected to the pads 24a to 24e. Even in this case, noise protection against the interconnects can be achieved for the same reason as described in each embodiment.

### Fourth Embodiment

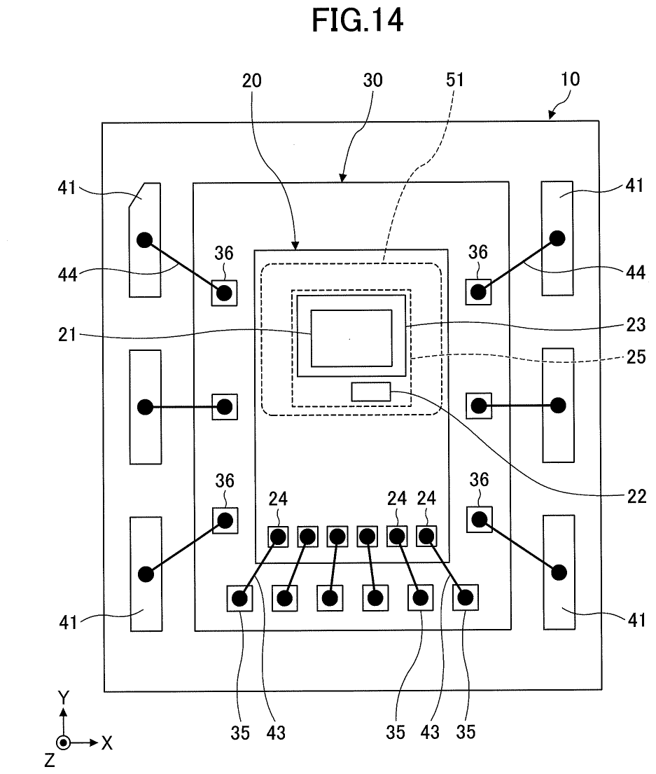

Hereafter, a fourth embodiment will be described with reference to FIGS. 14 to 22. In the present embodiment, a humidity detecting device has a same configuration as the humidity detecting device 10 according to the first embodiment, except for a temperature detecting unit, a heating unit, and a noise suppressing unit, as described below. Accordingly, explanation will be omitted for elements that are identical or sufficiently similar to elements that have been described in the first embodiment.

FIG. 14 is a plan view of an example of a humidity detecting device 10 from which the mold resin 40 is removed according to the present embodiment. In FIG. 14 as well, with respect to each of a sensor chip 20 and an ASIC chip 30, the planar shape is an approximate rectangle that has two sides parallel to the X direction and two sides parallel to the Y direction. The sensor chip 20 is smaller than the ASIC chip 30, and is disposed on a surface of the ASIC chip 30 via the first DAF 42.

In FIG. 14, with respect to the sensor chip 20, a humidity detecting unit 21, a temperature detecting unit 22, and a heating unit 23 are provided in an area exposed by an effective opening 51. The heating unit 23 is formed on the underside of the humidity detecting unit 21, so as to cover a region where the humidity detecting unit 21 is formed. In other words, an area of the heating unit 23 is larger than the humidity detecting unit 21. In such a manner, the mold resin 40 used as a sealing member seals the sensor chip 20 or the like in a manner such that the humidity detecting unit 21 and the temperature detecting unit 22 are exposed.

A plurality of bonding pads (which are hereafter simply referred to as pads) 24 are formed in an end portion of the sensor chip 20. In the present embodiment, six pads 24 are formed. The pads 24 are formed of aluminum or an aluminum-silicon alloy (AlSi), for example.

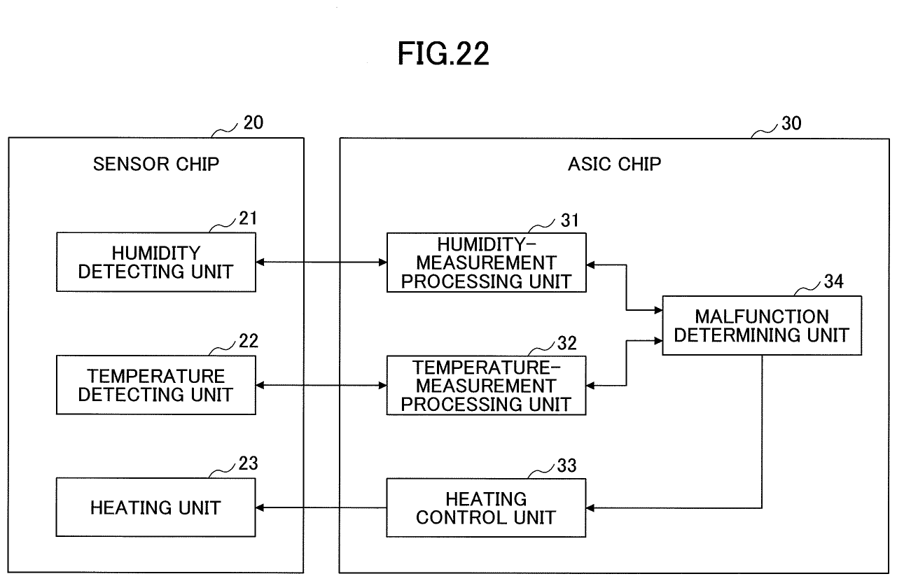

The ASIC chip 30 is a semiconductor chip for signal processing and control. On the ASIC chip 30, a humidity-measurement processing unit 31, a temperature-measurement processing unit 32, a heating control unit 33, and a malfunction determining unit 34 are formed, as described below (see FIG. 22).

In manufacturing, a position where the ASIC chip 30 is mounted is determined by a reference to lead terminals 41. A position where the sensor chip 20 is mounted on the ASIC chip 30 is determined by a reference to a position where either of the ASIC chip 30 or a given lead terminal 41 is disposed. The opening 50 is formed by transfer molding using a mold, or the like. In this case, a position of a mold is determined by a reference to the lead terminals 41.

A reference numeral 25 illustrated in FIG. 14 represents an allowed formation region where the humidity detecting unit 21 and the temperature detecting unit 22 are formed on the sensor chip 20. The allowed formation region 25 is set in a desired region in the opening 50 so as to ensure exposure of the humidity detecting unit 21 and the temperature detecting unit 22 from the opening 50, even in a case of largest displacement of the ASIC chip 30 or/and the sensor chip 20 from the mold occurring during mounting. The humidity detecting unit 21 and the temperature detecting unit 22 are reliably exposed from the opening 50 regardless of the above displacement, when they are disposed in the allowed formation region 25.

[Configuration of Sensor Chip]

Hereafter, a configuration of the sensor chip 20 will be described according to the present embodiment.

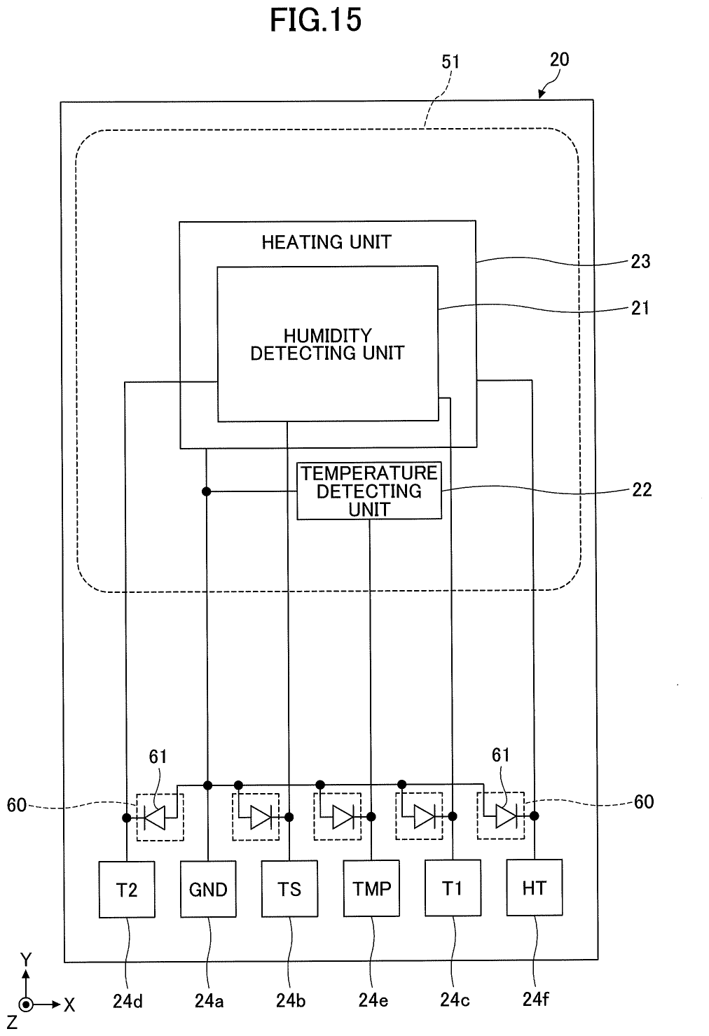

FIG. 15 is a schematic plan view of an example of a configuration of a sensor chip 20. The pads 24 are terminals that are used for applying a voltage from outside or detecting a potential. In FIG. 15, the respective pads 24 illustrated in FIG. 14 are distinctively indicated by pads 24a to 24f. Note that when it is not necessary to distinguish between the pads 24a and 24f, they may be simply referred to as pads 24.

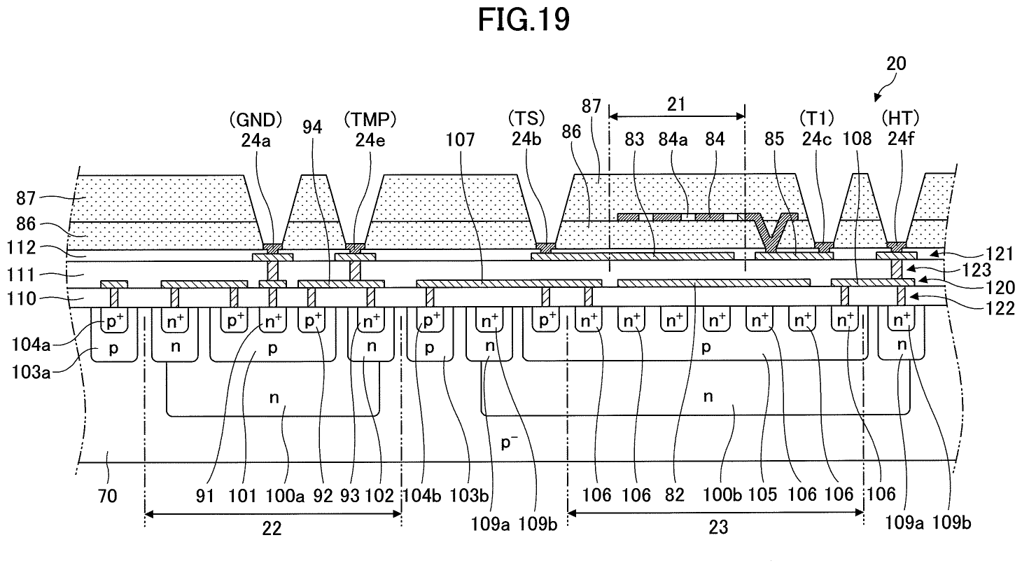

A pad 24a serves as a ground electrode terminal (GND) that is grounded to a ground potential. The pad 24a is electrically connected to units such as the temperature detecting unit 22 and the heating unit 23, via one or more corresponding interconnects or a substrate. The pad 24a is electrically connected to the p-type semiconductor substrate 70 (see FIG. 19) that constitutes part of the sensor chip 20.

A pad 24b is a signal terminal (TS) that is electrically connected to a lower electrode 83 of the humidity detecting unit 21. A pad 24c is a first drive terminal (T1) that is electrically connected to an upper electrode 84 of the humidity detecting unit 21. A pad 24d is a second drive terminal (T2) that is electrically connected to a reference electrode 82 (see FIG. 19) of the humidity detecting unit 21.

A pad 24e is a terminal for temperature detection (TMP) that is electrically connected to the temperature detecting unit 22. The pad 24e is used to acquire a detected signal of temperature. A pad 24f is a terminal for heating (HT) that is electrically connected to the heating unit 23. The pad 24f is used to supply a drive voltage for driving the heating unit 23.

Electrostatic-static discharge (ESD) protection circuits 60 are respectively connected to the pads 24b to 24f other than the pad 24a. Each ESD protection circuit 60 is connected between the pad 24a as a ground electrode terminal and a given pad as an input terminal or an output terminal from among the pads 24b to 24f. In the present embodiment, each ESD protection circuit 60 includes one diode 61. An anode of the diode 61 is connected to the pad 24a, and a cathode is connected to a given pad among the pads 24b to 24f.

Each ESD protection circuit 60 is preferably disposed in proximity to the pads 24b to 24f so as to be as far as possible away from the effective opening 51. Each ESD protection circuit 60 is sealed with the mold resin 40. Thereby, unwanted charge caused by the photoelectric effect is not generated.

[Configuration of ESD Protection Circuit]

Hereafter, a configuration of the ESD protection circuit 60 will be described according to the present embodiment.

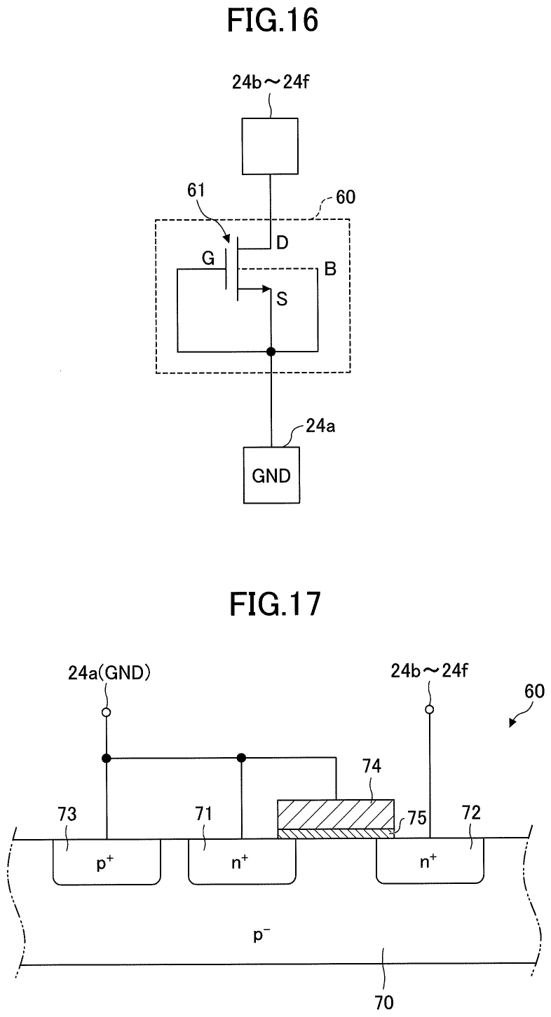

FIG. 16 is a circuit diagram illustrating an example of a configuration of the ESD protection circuit 60 according to the present embodiment. As illustrated in FIG. 16, a diode 61 that constitutes the ESD protection circuit 60 is formed by an NMOS transistor, in the similar manner as the first embodiment.

FIG. 17 is a diagram illustrating an example of a layer structure of the NMOS transistor that constitutes the ESD protection circuit 60. The NMOS transistor has two n-type diffusion layers 71 and 72, each of which is formed in a surface layer of a p-type semiconductor substrate 70 for constituting part of the sensor chip 20, a contact layer 73, and a gate electrode 74. The gate electrode 74 is formed on a surface of the p-type semiconductor substrate 70 via a gate insulating film 75. The gate electrode 74 is disposed between the two n-type diffusion layers 71 and 72.

[Configuration of Temperature Detecting Unit]

Hereafter, a configuration of the temperature detecting unit 22 will be described according to the present embodiment.

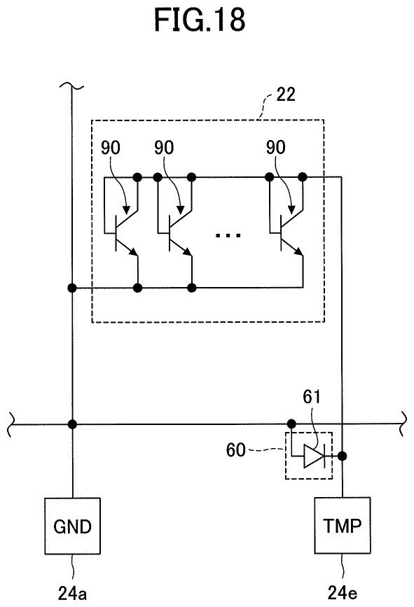

FIG. 18 is a circuit diagram illustrating an example of a configuration of the temperature detecting unit 22 according to the present embodiment. The temperature detecting unit 22 is a bandgap type temperature sensor that detects temperature by utilizing a physical property changing proportionally depending on a change in temperature, with respect to a bandgap of a semiconductor. For example, the temperature detecting unit 22 may include one or more bipolar transistors in which any two from among a base, an emitter and a collector are connected to each other to form two terminals. By detecting resistance between the two terminals, temperature can be measured.

As illustrated in FIG. 18, in the present embodiment, the temperature detecting unit 22 includes a plurality of (e.g., eight) npn-type bipolar transistors 90 connected in parallel, whose bases are connected to respective collectors. In such a manner, with respect to each of the plurality of bipolar transistors 90 connected in parallel, a junction area of a p-n junction is increased, thereby improving resistance properties in terms of ESD.

An emitter of each bipolar transistor 90 is connected to the pad 24a as a ground electrode terminal. A base and a collector of each bipolar transistor 90 are connected to the pad 24e as a terminal for temperature detection.

Temperature measurement is performed based on a potential at the pad 24e by a temperature-measurement processing unit 32 (see FIG. 22) in the ASIC chip 30.

[Element Structure of Sensor Chip]

Hereafter, an element structure of the sensor chip 20 will be described according to the present embodiment.

FIG. 19 is a schematic cross-sectional view for explaining an example of an element structure of the sensor chip 20. Note that in FIG. 19, the pads 24a, 24b, 24c and 24e are illustrated in a same cross section as the humidity detecting unit 21, the temperature detecting unit 22, and the heating unit 23, for facilitating understanding of the structure. This, however, does not mean that the pads are actually present in a same cross section. Also, a cross-section of each of the humidity detecting unit 21, the temperature detecting unit 22 and the heating unit 23 is simplified to facilitate understanding of the structure; accordingly, a positional relationship between those units, etc. is different from an actual one.

As illustrated in FIG. 19, the sensor chip 20 is formed using the p-type semiconductor substrate 70 described above. In the p-type semiconductor substrate 70, a first deep-n-well 100a and a second deep-n-well 100b are formed. The temperature detecting unit 22 is formed in the first deep-n-well 100a. The heating unit 23 is formed in the second deep-n-well 100b.

In a surface layer of the p-type semiconductor substrate 70 in which neither the first deep-n-well 100a nor the second deep-n-well 100b is formed, p-type diffusion layers 103a and 103b are formed. In respective surface layers of the p-type diffusion layers 103a and 103b, p-type contact layers 104a and 104b are formed. Each of the contact layers 104a and 104b is a low resistance layer (p-type diffusion layer) for electrically connecting a given interconnect layer formed over the p-type semiconductor substrate 70 to the p-type semiconductor substrate 70.

In a surface layer of the first deep-n-well 100a, a p-well 101 and an n-well 102 are formed. An n-type diffusion layer 91 and a p-type diffusion layer 92 are formed in a surface layer of the p-well 101. An n-type diffusion layer 93 is formed in a surface layer of the n-well 102. The n-type diffusion layer 91, the p-type diffusion layer 92, and the n-type diffusion layer 93 constitute the npn-type bipolar transistor 90 described above, and serve as an emitter, a base, and a collector, respectively.

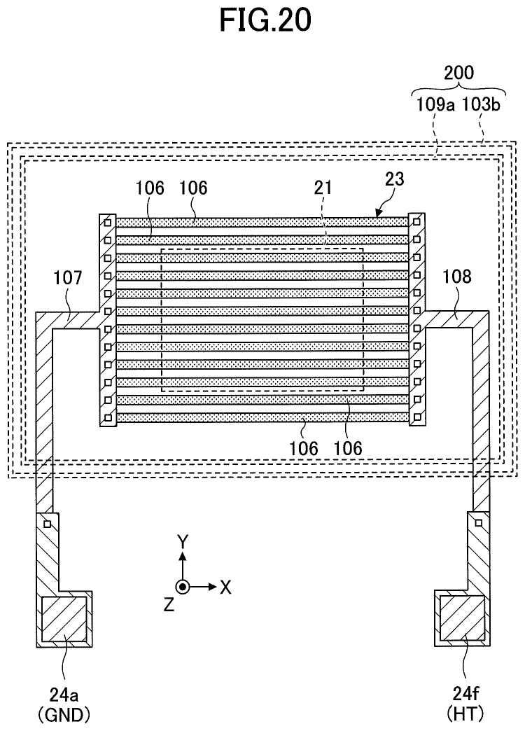

A p-well 105 is formed in a surface layer of the second deep-n-well 100b. One or more n-type diffusion layers 106 may be formed in a surface layer of the p-well 105. In the present embodiment, a plurality of n-type diffusion layers 106 are formed. For example, n-type diffusion layers 106 extend in a direction perpendicular to a plane of the paper, and are wholly arranged in a one-dimensional grating pattern (see FIG. 20). Each n-type diffusion layer 106 has a predetermined resistance value (e.g., a sheet resistance value of about 3Ω), and serves as a resistor that generates heat when a current flows. In such a manner, each n-type diffusion layer 106 constitutes the heating unit 23.

In the surface layer of the second deep n-well 100b, an n-type diffusion layer 109a is formed in the surroundings of the p-well 105 in which n-type diffusion layers 106 constituting part of the heating unit 23 are formed. An n-type contact layer 109b is formed in a surface layer of the n-type diffusion layer 109a.

The n-type diffusion layer 109a is formed to surround the periphery of the p-well 105. The p-type diffusion layer 103b is formed to surround the periphery of the n-type diffusion layer 109a. The n-type diffusion layer 109a and the p-type diffusion layer 103b constitute a guard ring 200 (see FIG. 20), which will be described later.

Each layer in the p-type semiconductor substrate 70 is formed by a general semiconductor manufacturing process (CMOS process). Each n-type diffusion layer 106 as a resistor is formed by a same manufacturing process as the n-type diffusion layers 91 and 93 that constitute part of the temperature detecting unit 22. The n-type diffusion layers 106, 91 and 93 and the contact layer 109b are formed simultaneously by an ion-implantation process in which a substrate is doped with an impurity used in ion implantation of an n-type impurity (e.g., phosphorus). In such a manner, each n-type diffusion layer 106 as a resistor has a same depth from the surface of the p-type semiconductor substrate 70 as the n-type diffusion layers 91 and 93 that constitute part of the temperature detecting unit 22. Each n-type diffusion layer 106 may have a same depth from the surface of the p-type semiconductor substrate 70 as the p-type diffusion layer 92 that constitutes part of the temperature detecting unit 22.

Note that the n-type diffusion layers 106, 91 and 93 and the contact layer 109b may be formed by a heating diffusion process in which an impurity is added by heat treatment, instead of an ion implantation process.

The n-type diffusion layers 71 and 72 of each of the ESD protection circuit 60 described above are also formed by a same manufacturing process (ion implantation process or thermal diffusion process) as the n-type diffusion layers 106, 91 and 93 and the contact layer 109b. The contact layer 73 is formed by a same manufacturing process (ion implantation process or thermal diffusion process) as the p-type diffusion layer 92, the contact layers 104a and 104b, and the like.

A first insulating film 110, the second insulating film 111, and a third insulating film 112 are sequentially laminated on the surface of the p-type semiconductor substrate 70. These are formed of an insulating material such as silicon dioxide (SiO₂) or silicon nitride (SiN).

A first interconnect layer 120 is formed on the first insulating film 110. A second interconnect layer 121 is formed on the second insulating film 111. The first interconnect layer 120 is overlaid with the second insulating film 111. The second interconnect layer 121 is overlaid with the third insulating film 111. Each of the first interconnect layer 120 and the second interconnect layer 121 is formed of a conductive material such as aluminum.

A first plug layer 122 that has a plurality of first plugs for connecting the first interconnect layer 120 to the p-type semiconductor substrate 70 is formed in the first insulating film 110. A second plug layer 123 that has a plurality of second plugs for connecting the first interconnect layer 120 to the second interconnect layer 121 is formed in the second insulating film 111. Each of the first plug layer 122 and the second plug layer 123 is formed of a conductive material such as tungsten.

For example, an interconnect 94 for connecting a base of each bipolar transistor 90 to a corresponding collector is formed in the first interconnect layer 120, and is connected to the p-type diffusion layers 92 and the n-type diffusion layers 93 via the first plug layer 122. The interconnect 94 is also connected to the pad 24e as a terminal for temperature detection via the second plug layer 123 and the second interconnect layer 121. The n-type diffusion layer 91 as an emitter of each bipolar transistor 90 is also connected to the pad 24a as a ground electrode terminal via the first plug layer 122, the first interconnect layer 120, and the second interconnect layer 121.

An interconnect 107 for grounding one end portion of the heating unit 23 to a ground potential is formed in the first interconnect layer 120, and is connected to each n-type diffusion layer 106 and the contact layer 104b via the first plug layer 122. An interconnect 108 for connecting another end portion of the heating unit 23 to the pad 24f as a terminal for heating is connected to each n-type diffusion layer 106 via the first plug layer 122, and is connected to the pad 24f via the second plug layer 123 and the second interconnect layer 121.

The reference electrode 82 used for the capacitor 81 for reference is formed by the first interconnect layer 120, and is connected to the pad 24d (not shown in FIG. 19) as the second drive terminal T2, via the second plug layer 123 and the second interconnect layer 121.

The lower electrode 83 used for the capacitor 80 for humidity detection is formed by the second interconnect layer 121, and is connected to the pad 24b as the signal terminal TS. Further, an interconnect 85 for connecting the upper electrode 84, which is used for the capacitor 80 for humidity detection, to the pad 24c as the first drive terminal T1 is formed by the second interconnect layer 121. Note that the lower electrode 83 is disposed at a location opposite to the reference electrode 82, via the second insulating film 111.

Each of the pads 24a to 24f is formed of a conductive material such as aluminum, and is disposed on the third insulating film 112. Each of the pads 24a to 24f is connected to the second interconnect layer 121, passing through the third insulating film 112.

The moisture sensitive film 86 is formed on the third insulating film 112. The moisture sensitive film 86 has a thickness of 0.5 μm to 1.5 μm, and is formed of a polymeric material that is capable of easily absorbing and desorbing the water molecule in accordance with the humidity. The moisture sensitive film 86 is a polyimide film that has a thickness of 1 μm, for example. Note that a polymeric material that forms the moisture sensitive film 86 is not limited to polyimide, and may include cellulose, polymethyl methacrylate (PMMA), polyvinyl alcohol (PVA), or the like.

An upper surface of the moisture sensitive film 86 is flat, and on this upper surface, a flat-plate type upper electrode 84 is formed. The upper electrode 84 is formed in a location opposite to the lower electrode 83, via the moisture sensitive film 86. A portion of the upper electrode 84 is connected to the interconnect 85. For example, the upper electrode 84 is a conductive film that is formed of aluminum metal that has a thickness of 200 nm, or the like. A plurality of openings 84a are also formed in the upper electrode 84 in order to efficiently incorporate water molecules in the air into the moisture sensitive film 86.

An overcoat film 87 is disposed on the moisture sensitive film 86 so as to cover the upper electrode 84. The overcoat film 87 is formed of a polymeric material, e.g., a same material as the moisture sensitive film 86. A thickness of the overcoat film 87 is 0.5 μm to 10 μm, for example.

Openings are formed in the moisture sensitive film 86 and the overcoat film 87 in order to expose the pads 24a to 24f.

In such a manner, the capacitor 80 for humidity detection, which is a parallel-plate type, is configured by the lower electrode 83 and the upper electrode 84. Also, the capacitor 81 for reference, which is a parallel-plate type, is configured by the lower electrode 83 and the reference electrode 82. The capacitor 80 for humidity detection as well as the capacitor 81 for reference are disposed over the heating unit 23.

In such a manner, when the heating unit 23 produces heat, the moisture sensitive film 86 is heated, between the lower electrode 83 and the upper electrode 84. Thereby, the moisture sensitive film 86 adsorbs an amount of water molecules in accordance with humidity, due to increased temperature upon heating. Accordingly, a permittivity of the moisture sensitive film 86 changes, and thus capacitance of the capacitor 80 for humidity detection is decreased. The temperature detecting unit 22 also detects increased temperature caused by the heating unit 23.

FIG. 20 is a plan view illustrating an example of the shape of the n-type diffusion layers 106 that constitute the heating unit 23. As illustrated in FIG. 20, the n-type diffusion layers 106 are arranged in a one-dimensional grid pattern, in which a plurality of elongated, rectangular regions are arranged parallel to each other. One end of each of the n-type diffusion layers 106 in the one-dimensional grid pattern is connected to the interconnect 107, and another end is connected to the interconnect 108. The heating unit 23 is positioned below the humidity detecting unit 21 so as to cover the entire humidity detecting unit 21.

In FIG. 20, a guard ring 200 includes an n-type diffusion layer 109a and a p-type diffusion layer 103b. The n-type diffusion layer 109a is connected to the second deep n-well 100b, and a potential at the pad 24f as the terminal for heating HT is applied to the n-type diffusion layer 109a. The n-type diffusion layer 109a is electrically connected to the p-well 105 via an interconnect 107, and a ground potential is applied to the p-well 105.

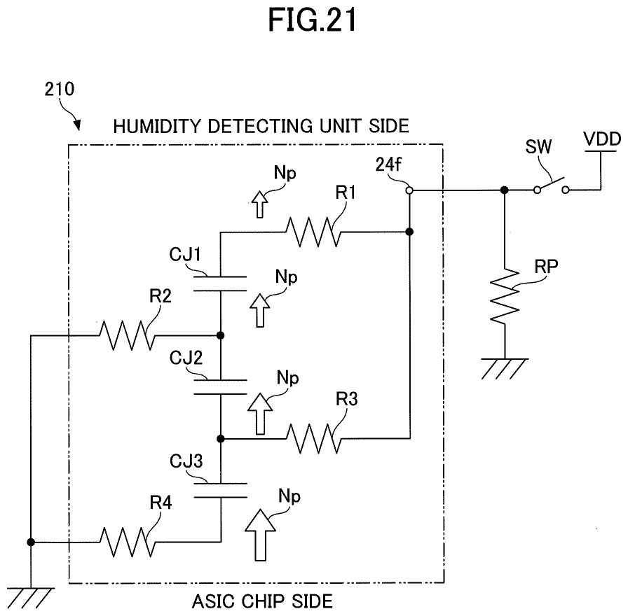

The guard ring 200 stabilizes a potential at the noise suppressing unit (noise suppressing layer) 210 (see FIG. 21) that is configured below the humidity detecting unit 21, in the p-type semiconductor substrate 70.

Note that the reference electrode 82 is disposed between the noise suppressing unit 210 and the lower electrode 83.

[Noise Suppressing Unit]

Hereafter, the function and operation of the noise suppressing unit will be described.

FIG. 21 is a diagram illustrating an example of an equivalent circuit of the noise suppressing unit 210 that is configured in the p-type semiconductor substrate 70. In FIG. 21, CJ1 denotes a junction capacitance of a p-n junction formed between layers of each n-type diffusion layer 106 and the p-well 105. CJ2 denotes a junction capacitance of a p-n junction formed between layers of the p-well 105 and the second deep n-well 100b. CJ3 denotes a junction capacitance of a p-n junction formed between layers of the second deep n-well 100b and the p-type semiconductor substrate 70.

R1 denotes diffusion resistance of one or more n-type diffusion layers 106. R2 denotes diffusion resistance of the p-well 105. R3 denotes diffusion resistance of the second deep n-well 100b. R4 denotes substrate resistance of the p-type semiconductor substrate 70.

The noise suppressing unit 210 includes one or more n-type diffusion layers 106, the p-well 105, the second deep n-well 100b, and the p-type semiconductor substrate 70. In other words, the noise suppressing unit 210 has a laminated structure consisting of four semiconductor layers of which polarities are alternately inverted. In the present embodiment, the noise suppressing unit 210 has an npnp-type structure.

For example, a power supply voltage VDD is supplied to the pad 24f as the terminal for heating HT, via a pull-down resistor RP and a switch circuit SW. When the heating unit 23 is driven, the switch circuit SW is turned on, so that the power supply voltage VDD as a drive voltage is supplied to the pad 24a. In this case, the n-type diffusion layers 106 as resistors generate heat, and each p-n junction included in the noise suppressing unit 210 is reverse-biased.

When the heating unit 23 is not driven, the switch circuit SW is turned off to be in a pull-down state, so that the pad 24a is grounded via the pull-down resistor RP.

An arrow Np in FIG. 21 indicates the magnitude of a peak voltage of noise generated by the ASIC chip 30, the noise being transmitted to the humidity detecting unit 21. In such a manner, the noise suppressing unit 210 decreases the noise peak voltage by dividing the peak voltage with a capacitor formed across each p-n junction. Noise N of which a peak voltage is decreased by the noise suppressing unit 210 is transmitted to the humidity detecting unit 21. In the humidity detecting unit 21, the effect of the noise on a humidity detecting operation is suppressed.

Note that the noise suppressing unit 210 has a similar effect on suppression of the noise that is generated by the sensor chip 20, the noise being transmitted to the ASIC chip 30.

[Configuration of ASIC Chip]

Hereafter, a configuration of the ASIC chip 30 will be described according to the present embodiment.

FIG. 22 is a block diagram illustrating an example of a configuration of the ASIC chip 30. As illustrated in FIG. 22, the ASIC chip 30 includes a humidity-measurement processing unit 31, a temperature-measurement processing unit 32, a heating control unit 33, and a malfunction determining unit 34.

The humidity-measurement processing unit 31 has a same configuration as the ASIC chip 30 described in the first embodiment in FIG. 10. In the present embodiment, the humidity-measurement processing unit 31 follows the measurement sequence illustrated in FIG. 11 to calculate relative humidity (% RH) in a same manner as the ASIC chip 30 according to the first embodiment.

The temperature-measurement processing unit 32 detects a potential at the pad 24e as a terminal for temperature detection, and calculates temperature corresponding to the detected potential.

The heating control unit 33 applies a predetermined drive voltage (e.g., the above power supply voltage VDD) to the pad 24f as a terminal for heating, and causes the heating unit 23 to which a current (e.g., about 10 mA) flows to produce heat. The heating control unit 33 controls an amount of produced heat, by controlling a voltage applied to the pad 24f.

The malfunction determining unit 34 determines whether the humidity detecting device 10 malfunctions based on relative humidity measured by the humidity-measurement processing unit 31 and temperature measured by the temperature-measurement processing unit 32. In determination of malfunction, the malfunction determining unit 34 transmits, to the heating control unit 33, an instruction to start or finish heating by the heating unit 23.

For example, in an initial state where the heating unit 23 does not generate heat, the malfunction determining unit 34 acquires humidity H1 from the humidity-measurement processing unit 31, and acquires temperature T1 from the temperature-measurement processing unit 32. Next, the malfunction determining unit 34 causes the heating unit 23 to start heating. After a certain period of time, the malfunction determining unit 34 further acquires humidity H2 from the humidity-measurement processing unit 31, and acquires temperature T2 from the temperature-measurement processing unit 32.

When temperature is increased by heating (T2>T1) and humidity is decreased by heating (H2<H1), the malfunction determining unit 34 determines that the humidity detecting device 10 is in a normal state, and otherwise determines that the humidity detecting device 10 malfunctions.

[Effect]

As described in the measurement sequence, the ASIC chip 30 generates an AC drive signal, and applies it to the humidity detecting unit 21 of the sensor chip 20, which might result in generating large noise in the ASIC chip 30. However, in the present embodiment, the noise suppressing unit 210 disposed below the humidity detecting unit 21 (on the ASIC chip 30 side) decreases a peak voltage of noise that is transmitted from the ASIC chip 30 to the humidity detecting unit 21. Thereby, the effect of noise on the humidity detecting unit 21 is suppressed, so that protection against the noise is thereby improved.

In order to suppress such noise, it is considered that an insulating layer may be interposed between the sensor chip 20 and the ASIC chip 30. However, it is undesirable to dispose the insulating layer between the chips because there is a need for downsizing and thinning of each chip.

[Modifications]

In the fourth embodiment, the noise suppressing unit 210 includes four laminated semiconductor layers of which polarities are alternately inverted. However, the number of semiconductor layers that constitutes the noise suppressing unit is not limited to the example described above, and may be two or more.

In the fourth embodiment, the sensor chip 20 is formed with the p-type semiconductor substrate 70. Instead of such a manner, an n-type semiconductor substrate can be used.

In the fourth embodiment, the humidity detecting unit 21 is a moisture sensor of the capacitive humidity type, but may be a resistance-changing type humidity sensor such as the piezoresistive type, which detects a change in the resistance of a moisture sensitive film due to absorption and dehumidification.

The present disclosure can also be applied to a detecting device that detects physical properties other than humidity. For example, instead of the humidity detecting unit 21, a detecting unit for outputting a signal indicative of a physical property other than humidity may be used.

In the present disclosure, with respect to the term “cover” or “on” that involves a positional relationship between given two elements, such a term means both cases where a first element is disposed on a surface of a second element indirectly via other element(s) and where a first element is disposed on a surface of a second element directly.

Explanation has been provided above for the present disclosure in relation to one or more embodiments. However, the present disclosure is not limited to the embodiments as described, and changes or alternatives can be made within the spirit of the present disclosure.

What is claimed is:

1. A detecting device comprising;
a substrate;
a detecting unit disposed over the semiconductor substrate, the detecting unit being configured to output a signal in response to a physical property; and
a noise suppressing layer disposed below the detecting unit and in the semiconductor substrate, or, disposed between the detecting unit and the semiconductor substrate.

2. The detecting device according to claim 1, wherein the noise suppressing layer is a diffusion layer that has an opposite polarity of the semiconductor substrate.

3. The detecting device according to claim 2, wherein a constant potential is supplied to the noise suppressing layer such that a p-n junction formed between the noise suppressing layer and the semiconductor substrate is reverse-biased.

4. The detecting device according to claim 1, wherein the noise suppressing layer is disposed between the detecting unit and the semiconductor substrate, and wherein the noise suppressing layer is a conductive layer formed of metal or polycrystal silicon.

5. The detecting device according to claim 1, wherein the detecting unit includes a capacitor for humidity detection in which a moisture sensitive film is disposed between a pair of opposite electrodes, and wherein the detecting unit is configured to output a signal in response to humidity.

6. The detecting device according to claim 5, wherein the capacitor for humidity detection includes:
a lower electrode disposed over the semiconductor substrate,
an upper electrode disposed on the moisture sensitive film, and
the moisture sensitive film disposed between the lower electrode and the upper electrode.

7. The detecting device according to claim 6, wherein the detecting unit includes:
the lower electrode,
a reference electrode disposed between the noise suppressing layer and the lower electrode, and
an insulating film disposed between the reference electrode and the lower electrode.

8. The detecting device according to claim 5, wherein the moisture sensitive film is formed of polyimide.

9. The detecting device according to claim 1, further comprising a second semiconductor chip including a drive unit and a charge-voltage converting unit, the drive unit being configured to drive the detecting unit, and the charge-voltage converting unit being configured to convert an electric charge carried by the detecting unit into a voltage,
wherein the semiconductor substrate, the detecting unit, and the noise suppressing unit are integrated as a first semiconductor chip, and
wherein the first semiconductor chip is disposed over the second semiconductor chip.

10. The detecting device according to claim 9, wherein the drive unit is configured to apply an alternating current drive signal to the detecting unit.

11. A detecting device comprising:
a first semiconductor chip including a semiconductor substrate and a detecting unit disposed over the semiconductor substrate, the detecting unit being configured to output a signal in response to a physical property;
a second semiconductor chip including a drive unit and a charge-voltage converting unit, the drive unit being configured to drive the detecting unit, and the charge-voltage converting unit being configured to convert an electric charge carried by the detecting unit into a voltage; and
a noise suppressing layer between the detecting unit and the second semiconductor chip,
wherein the first semiconductor chip is disposed over the second semiconductor chip.

12. The detecting device according to claim 11, wherein the noise suppressing layer is disposed between the detecting unit and the semiconductor substrate.

13. The detecting device according to claim 11, wherein the noise suppressing layer is disposed below the detecting unit, in the semiconductor substrate.

14. The detecting device according to claim 1, wherein the noise suppressing layer is disposed below the detecting unit, in the semiconductor substrate, and wherein the noise suppressing layer includes a plurality of laminated semiconductor layers of which polarities are alternately inverted.

15. The detecting device according to claim 14, wherein a voltage is applied to each p-n junction formed between adjacent semiconductor layers from among the plurality of laminated semiconductor layers, so that each p-n junction is reverse-biased.

16. The detecting device according to claim 14, wherein the noise suppressing layer includes at least one diffusion layer formed in a surface layer of the semiconductor substrate, and wherein the diffusion layer is configured to serve as a resistor that produces heat, in response to a current flowing to the diffusion layer.

17. The detecting device according to claim 11, wherein the noise suppressing layer is disposed below the detecting unit, in the semiconductor substrate, and wherein the noise suppressing layer includes a plurality of laminated semiconductor layers of which polarities are alternately inverted.
